(19) United States
(12) Patent Application Publication
(10) Pub. No.: US 2004/0113101 A1
(43) Pub. Date: Jun. 17, 2004

(54) Charged-particle-beam microlithography systems that detect and offset beam-perturbing displacements of optical-column components

(75) Inventors: Shiwen Li, Kawasaki-shi (JP); Takaharu Miura, Yamato City (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation

(21) Appl. No.: 10/654,804

(22) Filed: Sep. 3, 2003

(30) Foreign Application Priority Data
Sep. 3, 2002 (JP) 2002-257939

(51) Int. Cl. H01J 37/304

(52) U.S. Cl. 250/492.22

(57) ABSTRACT

Charged-particle-beam (CPB) microlithography systems are disclosed that detect displacements of certain components and implement corrective countermeasures to the displacements so that pattern-exposure accuracy and precision are not compromised by the displacements. In an embodiment, displacement sensors and corrective actuators are installed at respective locations in or on the microlithography system. If the displacement sensors detect displacements at the respective locations, corresponding electrical signals produced by the sensors are fed-back or fed-forward to the corrective actuators. Alternatively, the electrical signals are routed directly to a beam-position-control system or routed indirectly to a displacement predictor. The displacement predictor calculates estimates of displacements based on data obtained previously concerning operation of certain displacement-generating components of the system. The estimates are used in feed-forward control of the beam position in the microlithography system, thereby improving pattern-transfer performance of the system.

### FIELD

This disclosure pertains to microlithography, which involves projection-transfer of a pattern, from a reticle or other pattern-master, to a suitable lithographic substrate (e.g., semiconductor wafer or the like) capable of being imprinted with a projected image of the pattern. More specifically, the disclosure pertains to microlithography performed using a charged particle beam (e.g., electron beam or ion beam) as a lithographic energy beam. Even more specifically, the disclosure pertains to charged-particle-beam (CPB) microlithography systems that detect vibrations and other unwanted displacements (movements) of certain key components of the system and that implement countermeasures to the displacements so that pattern-transfer accuracy is not compromised by the displacements.

### BACKGROUND

With the relentless demands for ever-finer pattern-transfer resolution in microlithography, the inability of conventional optical microlithography to keep pace with these demands has become increasingly limiting. As a result, substantial effort currently is being expended to develop a practical “next generation lithography” (NGL) technology. One of the most promising NGL approaches currently is charged-particle-beam (CPB) microlithography which uses an electron beam or ion beam (most commonly an electron beam) as the lithographic energy beam.

An electron-beam microlithography system, as an exemplary CPB microlithography system, irradiates an electron beam (“illumination beam”) to a selected region on a pattern-defining reticle to form a “patterned beam” (carrying an aerial image of the illuminated region of the reticle) and irradiates the patterned beam on a corresponding region of a lithographic substrate (e.g., resist-coated semiconductor wafer) to imprint the image in the resist. The illumination beam and patterned beam pass through respective optical systems that typically are contained in respective “columns” each containing a respective arrangement of CPB lenses, deflectors, apertures, and the like. Since charged particle beams are greatly attenuated by the ambient atmosphere, CPB microlithography must be performed under high-vacuum conditions. Hence, the illumination-beam column and the patterned-beam column are situated in respective chambers that are coupled via respective exhaust conduits and gate valves to respective vacuum pumps, usually including respective turbomolecular pumps. Also, the reticle and substrate are placed on respective stages that are massive and must move at high respective velocities, accelerations, and decelerations.

The various components summarized above, such as the stages, vacuum pumps, and gate valves, pose as respective sources of potentially troublesome vibrations and other displacements that can be conducted throughout the system. By “troublesome” is meant that the displacements can (and typically do) cause, as a result of consequential beam-position errors, losses in exposure accuracy and resolution achievable by the system. For example, whenever vibration is transmitted to the illumination-optical system (system used for illuminating the selected region of the reticle) or projection-optical system (system for forming the imprinting image on the resist-coated substrate), projection accuracy, precision, and resolution are degraded. Displacements transmitted to the illumination-optical-system (IOS) column and/or, especially, the projection-optical-system (POS) column can be transmitted easily to constituent components (e.g., lenses and/or deflectors) of these columns. A vibrating or otherwise moving component such as a lens or deflector simply does not exhibit as high a level of lithographic-exposure performance as a stationary component. Hence, there is a need for CPB microlithography systems exhibiting more complete attenuation than currently obtainable of displacements of key components than extant in conventional CPB microlithography systems.

### SUMMARY

To ends as summarized above, the subject claims provide, inter alia, charged-particle-beam (CPB) microlithography systems that implement countermeasures so that the accuracy and precision with which the pattern is transferred to the lithographic substrate is not adversely affected due to vibrations or other displacements of respective portions of the microlithography system.

According to a key aspect of the invention, CPB microlithography systems are provided that selectively irradiate a charged particle beam onto a sensitive substrate to imprint a pattern on the substrate. An embodiment of such a system comprises a CPB-optical column, at least one displacement sensor, and a beam-corrector. The CPB-optical column is situated upstream of the substrate and comprises a beam-position-control portion that deflects and resolves a charged particle beam for making a lithographic exposure of the pattern on the sensitive substrate. The at least one displacement sensor is attached to a location in or on the CPB-optical column, and is configured to detect displacements, that could produce a beam-position error, of the location and to produce electrical signals corresponding to the detected displacements. The beam-corrector is connected so as to receive the electrical signals from the at least one displacement sensor and to produce beam-correction signals corresponding to the electrical signals. The beam-correction signals are received by the beam-position-control portion, which imparts a corresponding correction to the beam serving to correct the beam-position error. The beam-position-control portion can comprise at least one CPB lens and at least one CPB deflector. The correction can involve, for example, changes in deflection of the beam or changes in lensing of the beam. The displacement sensor can be, for example, an acceleration sensor, a force sensor, or a relative-movement sensor.

The CPB-optical column can comprise an illumination-optical-system column, wherein the beam-corrector can be situated and configured to impart a correction to the beam propagating through the illumination-optical-system column. Alternatively or in addition, the CPB-optical column can comprise a projection-optical-system column, wherein the beam-corrector can be situated and configured to impart a correction to the beam propagating through the projection-optical-system column (and possibly also the illumination-optical-system column).

The CPB-optical column can comprise a reticle chamber and a wafer chamber each containing a subatmospheric-pressure environment produced by a vacuum system connected to the CPB-optical column. In this configuration the detected displacements can include vibration of at least one of the chambers caused by operation of the vacuum system.

The system can include multiple displacement sensors attached to respective locations on or in the CPB-optical column, for detecting respective displacements of the locations. For example, the multiple displacement sensors can be attached to respective components of the CPB-optical column, so as to detect respective displacements of the respective components. These components can include respective components of the beam-position-control portion, wherein the respective displacements arise from energization of the respective components.

The beam-corrector can comprise at least one actuator situated relative to a component of the beam-position-control portion and configured to impart a respective positional shift of the component in response to the beam-correction signal. The positional shift serves to correct the beam-position error.

The beam-corrector can comprise a processor connected to the at least one displacement sensor. In this configuration the processor is configured to: (a) ascertain, from the electrical signals from the at least one displacement sensor, whether a beam correction is indicated to correct an effect of the displacement, (b) if beam correction is indicated, to produce the beam-correction signals corresponding to the electrical signals, and (c) route the beam-correction signals to the beam-position-control portion to impart the correction to the beam serving to correct the beam-position error. The processor can be configured to cause the beam-position-control portion to impart a compensating manipulation of the beam to correct the beam-position error. The compensating manipulation can be a deflection of the beam. The processor can be configured to control, in a feed-back manner, operation of the beam-position-control portion to perform a compensating manipulation of the beam, wherein the compensating manipulation is in real time with respect to the displacement.

The beam-corrector can comprise a predictor that computes an estimated beam-position error from the detected displacement of the location and produces the beam-correction signals in a feed-forward manner. The predictor can be configured to receive drive signals routed to components of the microlithography system, calculate estimates of beam-position error that could be caused by energization of the components according to the drive signals, and correct the calculated beam-position error by feed-forward control of the beam-corrector. This system further can comprises a stage situated and configured to hold a reticle or the substrate in the CPB-optical column. In this configuration the beam-corrector can be configured to impart, in response to receiving the beam-correction signals, a compensating motion of the stage.

Another embodiment of a CPB microlithography system comprises a CPB-optical system, a stage, an interferometer, at least one displacement sensor, and a beam-corrector. The CPB-optical system includes a beam-position-control portion that controllably deflects and resolves a charged particle beam for making a lithographic exposure of the pattern on the sensitive substrate. The stage is situated relative to the CPB-optical system and is configured to hold and controllably move a pattern-defining reticle or the substrate during the making of the lithographic exposure. The interferometer is situated relative to the stage and is configured to determine a position of the stage. The at least one displacement sensor is attached to a respective location on at least one of the stage and interferometer, wherein the displacement sensor is configured to detect a displacement of the location, including a displacement producing a beam-position error that could degrade accuracy of the lithographic exposure, and to produce electrical signals corresponding to the detected displacement. The beam-corrector is connected so as to receive the electrical signals from the at least one displacement sensor and to produce beam-correction signals corresponding to the electrical signals. The beam-correction signals are received by the beam-position-control portion, which imparts a correction to the beam serving to correct the beam-position error.

The CPB-optical system can comprise an illumination-optical-system column and a projection-optical-system column each including respective beam-position-control portions. In this configuration the respective beam-position-control portions receive beam-correction signals so as to impart respective corrections to the beam. This configuration can include multiple stages, including a reticle stage situated relative to the illumination-optical-system column and configured to hold a pattern-defining reticle, and a substrate stage situated relative to the projection-optical-system column and configured to hold the sensitive substrate. Each of the reticle stage and substrate stage desirably include a respective interferometer. This system can include multiple displacement sensors including respective displacement sensors coupled to the illumination-optical-system column, the projection-optical-system column, the reticle stage, and the substrate stage. The beam-corrector in this configuration can be configured to produce respective beam-correction signals for the respective beam-position-control portions of the illumination-optical-system column and projection-optical-system column as required to correct a displacement detected in one or both columns.

The beam-corrector can comprise at least one actuator situated relative to a component of the beam-position-control portion and configured to impart a respective positional shift of the component in response to the beam-correction signal, wherein the positional shift serves to correct the beam-position error.

The beam-corrector can comprise a processor connected to the at least one displacement sensor. In this configuration the processor desirably is configured to: (a) ascertain, from the electrical signals from the at least one displacement sensor, whether a beam correction is indicated to correct an effect of the displacement, (b) if beam correction is indicated, to produce the beam-correction signals corresponding to the electrical signals, and (c) route the beam-correction signals to the beam-position-control portion to impart the correction to the beam serving to correct the beam-position error.

The beam-corrector can comprise a predictor that computes an estimated beam-position error from the detected displacements of the location and produces the respective beam-correction signals in a feed-forward manner. The predictor can be configured to: (a) receive drive signals routed to components of the microlithography system, (b) calculate estimates of beam-position error that could be caused by energization of the components according to the drive signals, and (c) correct the calculated beam-position error by feed-forward control of the beam-corrector.

Yet another embodiment of a CPB microlithography system comprises a CPB-optical system, a stage (with interferometer), multiple displacement sensors, and a beam-corrector. The CPB-optical system includes a beam-position-control portion that controllably deflects and resolves the charged particle beam for making a lithographic exposure of the pattern on the sensitive substrate. The stage is situated relative to the CPB-optical system and is configured to hold and controllably move a pattern-defining reticle or the substrate during the making of the lithographic exposure. The interferometer is situated relative to the stage and is configured to determine the position of the stage. The displacement sensors are attached to respective locations on the stage or interferometer, and on the CPB-optical system or beam-position-control portion. The displacement sensors are configured to detect a displacement of the respective location, including displacements that could produce a beam-position error that degrades accuracy of the lithographic exposure, and to produce respective electrical signals corresponding to the detected displacements. The beam-corrector is connected so as to receive the electrical signals from the displacement sensors and to produce respective beam-correction signals that are routed to and received by the beam-position-control portion. The beam-position-control portion, upon receiving the beam-correction signals, imparts a respective correction to the beam serving to correct the beam-position error.

The beam-corrector in this embodiment can comprise a predictor that computes an estimated beam-position error from the detected displacements of the respective locations and produces the respective beam-correction signals in a feed-forward manner. The predictor can be configured to: (a) receive drive signals routed to components of the microlithography system, (b) calculate estimates of beam-position error that could be caused by energization of the components according to the drive signals, and (c) correct the calculated beam-position error by feed-forward control of the beam-corrector.

The system further can comprise a correlation converter connected to the predictor. The correlation converter can be configured to produce electrical signals based on data concerning correlations of displacement-sensor signals with actual substrate location, and to route these electrical signals to the predictor which calculates the estimates of beam-position error based at least in part on these electrical signals. The system further can comprise a beam-deflection controller connected to the predictor. The beam-deflection controller can be configured to cause deflection of the beam, according to the beam-correction signals, as required to correct the beam-position error.

A CPB microlithography system according to yet another embodiment comprises a CPB-optical system, a stage, multiple displacement sensors, and a beam-corrector. The CPB-optical system is situated upstream of the substrate and comprises an optical column and a beam-position-control portion. The beam-position-control portion controllably deflects and resolves a charged particle beam for making a lithographic exposure of the pattern on the sensitive substrate. The optical column comprises a vacuum chamber to which is connected a vacuum system. The stage is situated relative to the CPB-optical system and is configured to hold a pattern-defining reticle or the substrate during the making of the lithographic exposure. The stage includes a stage actuator that is configured to move the stage in a controlled manner. The displacement sensors are attached to respective locations, including the stage actuator and vacuum system, that tend to produce displacements. The displacement sensors are configured to detect the displacements at the respective locations, and to produce respective electrical signals corresponding to the detected respective displacements. The beam-corrector is connected so as to receive the electrical signals from the displacement sensors. The beam-corrector comprises a predictor configured to calculate estimates of displacement of one or more of the optical column, the beam-position-control portion, the vacuum system, and the stage. The predictor also is configured to correct, based on the estimates provided by the predictor, the beam-position error by feed-forward control.

The system further can comprise a correlation converter connected to the predictor, wherein the correlation converter produces electrical signals based on data concerning correlations of displacement-sensor signals with actual substrate location. These electrical signals are routed to the predictor which calculates the estimates of beam-position error based at least in part on these electrical signals.

The system further can comprise a beam-deflection controller connected to the predictor. The beam-deflection controller causes deflection of the beam, according to the beam-correction signals, as required to correct the beam-position error.

A CPB microlithography system according to yet another embodiment comprises a CPB-optical system, a stage, a processor, and a beam-corrector. The CPB-optical system comprises a beam-position-control portion and a vacuum chamber to which is connected a vacuum system. The beam-position-control portion controllably deflects and resolves a charged particle beam for making a lithographic exposure of the pattern on the sensitive substrate. The stage is situated relative to the CPB-optical system and is configured to hold a pattern-defining reticle or the substrate during the making of the lithographic exposure. The stage includes a stage actuator that is configured to move the stage in a controlled manner. The processor is connected to the beam-position-control portion, the vacuum system, and the stage actuator. The processor is configured to produce, in a coordinated manner, respective drive signals for the beam-position-control portion, the vacuum system, and the stage actuator. The beam-corrector comprises a predictor configured to: (a) receive the drive signals, (b) calculate estimates of respective displacements caused by driving the beam-position-control portion, the vacuum system, and the stage, and (c) calculate an expected beam-position error caused by the displacements. The beam-corrector is configured to correct the beam-position error by feed-forward control.

This system further can comprise a correlation converter connected to the predictor. The correlation converter produces electrical signals based on data concerning correlations of at least one drive signal with actual substrate location. These electrical signals are routed to the predictor, which calculates the estimates of beam-position error based at least in part on these electrical signals.

This system further can comprise a beam-deflection controller connected to the predictor. The beam-deflection controller can cause deflection of the beam, according to the beam-correction signals, as required to correct the beam-position error.

A CPB microlithography system according to yet another embodiment comprises a CPB-optical system, multiple displacement sensors, and at least one damping actuator. The CPB-optical system is situated upstream of the substrate and comprises an optical column and a beam-position-control portion. The beam-position-control portion is configured to deflect and resolve, in a controlled manner, a charged particle beam for making a lithographic exposure of the sensitive substrate. The multiple displacement sensors are attached to respective locations on the optical column and the beam-position-control portion, and are configured to detect displacements of the respective locations that could adversely impart a beam-position error and to produce electrical signals corresponding to the detected displacements. The at least one damping actuator is attached to the lens column or beam-position-control portion, and is configured to receive the electrical signals from the displacement sensors and to restrict, based on the signals, displacement of the optical column or beam-position-control portion. The system further can comprise a processor that receives the electrical signals corresponding to the detected displacements, and processes the electrical signals to produce drive signals for at least one of the optical column and beam-position-control portion. The drive signals cause the displacement of the optical column or the beam-position-control portion. In this configuration the damping actuator can be an electromagnetic actuator or a piezoelectric actuator.

A CPB microlithography system according to yet another embodiment comprises a component that, when actuated, produces a displacement that, if unchecked, could produce an excessive beam-position error. The system also includes a displacement sensor that is attached to the component and is configured to detect displacements of the component and to produce electrical signals corresponding to the detected displacements. The system also includes a damping actuator attached to the component and connected to the displacement sensor so as to receive the electrical signals from the displacement sensor. The damping actuator is configured, when actuated, to attenuate the displacement of the component in a feed-forward manner. Alternatively, the damping actuator can be configured to respond to the displacement sensor in a feed-back controlled manner. The component can be of an assembly such as a stage, a vacuum system, or a beam-position-control portion.

A CPB microlithography system according to yet another embodiment comprises a CPB-optical system, a stage, a controller, a predictor, and a damping actuator. The CPB-optical system is situated upstream of the substrate and comprises a beam-position-control portion that, when energized, controllably deflects and resolves the charged particle beam for making a lithographic exposure of the pattern on the sensitive substrate. The CPB-optical system can be a part of an optical column to which a vacuum system is connected, wherein the vacuum system is configured, when energized, to evacuate the optical column to a desired vacuum level. The stage is situated relative to the CPB-optical system and configured to hold, in the optical column, a pattern-defining reticle or the substrate during the making of the lithographic exposure. The stage includes a stage actuator that is situated and configured, when energized, to move the stage in a controlled manner. Each of the optical column, the stage, and the beam-position-control portion are capable of producing, when energized, a respective beam-position error. The controller is connected to the beam-position-control portion, the vacuum system, and the stage actuator. The controller is configured to deliver respective drive signals to the beam-position-control portion, the vacuum system, and the stage actuator. The predictor is connected so as to receive the drive signals, and is configured to calculate estimates of respective displacements produced by the energized beam-position-control portion, the optical column, and the stage actuator. A respective damping actuator is connected to at least one of the optical column, the beam-position-control portion, and the stage. Each damping actuator is configured to restrict, in a feed-forward manner, the respective displacements based on the calculated estimates. This system further can comprise a correlation converter and beam-deflection controller as summarized above.

A CPB microlithography system according to yet another embodiment comprises a CPB-optical system and at least one displacement damper. The CPB-optical system is situated upstream of the substrate, and comprises a CPB-optical column and a beam-position-control portion. The beam-position-control portion is configured to deflect and resolve the charged particle beam in a controlled manner for making a lithographic exposure of the pattern on the sensitive substrate. The at least one displacement damper is attached to the CPB-optical column or the beam-position-control portion, and is configured, when energized, to dampen displacements of the CPB-optical column or beam-position-control portion, respectively. The displacement damper can be configured to dampen the displacement, based on fed-forward data to the displacement damper concerning an expected displacement of the CPB-optical column or beam-position-control portion, respectively.

The foregoing and additional features and advantages of the invention will be more readily apparent from the following detailed description, which proceeds with reference to the accompanying drawings.

### BRIEF EXPLANATION OF THE DRAWINGS

FIG. 1 is an elevational view (with partial section) showing certain structural features of a microlithography system according to a representative embodiment.

FIG. 2 is an elevational view (with partial section) showing the configuration of a beam-position-control portion of an illumination-optical-system (IOS) column or projection-optical-system (POS) column of a microlithography system, according to a representative embodiment.

FIG. 3 is a plan view depicting an exemplary arrangement of electromagnetic actuators around a mounting flange of an IOS column.

FIG. 4 is an elevational view of an IOS column relative to braces and electromagnetic actuators, according to a representative embodiment.

FIG. 5 is a block diagram depicting an embodiment of feed-back and feed-forward control of the beam-deflector electrode system of the microlithography system.

FIG. 6 is an elevational schematic diagram showing image-formation relationships and control systems of an embodiment of an electron-beam, divided-reticle projection-microlithography system, according to an embodiment.

FIG. 7 is an oblique view schematically depicting pattern transfer from the reticle to the substrate, as performed using the system of FIG. 6

### DETAILED DESCRIPTION

The invention is described below in the context of representative embodiments that are not intended to be limiting in any way.

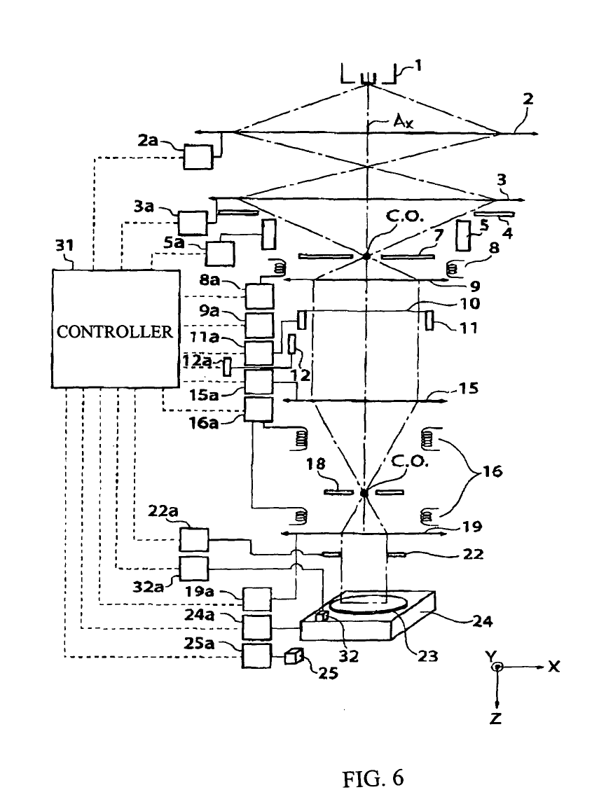

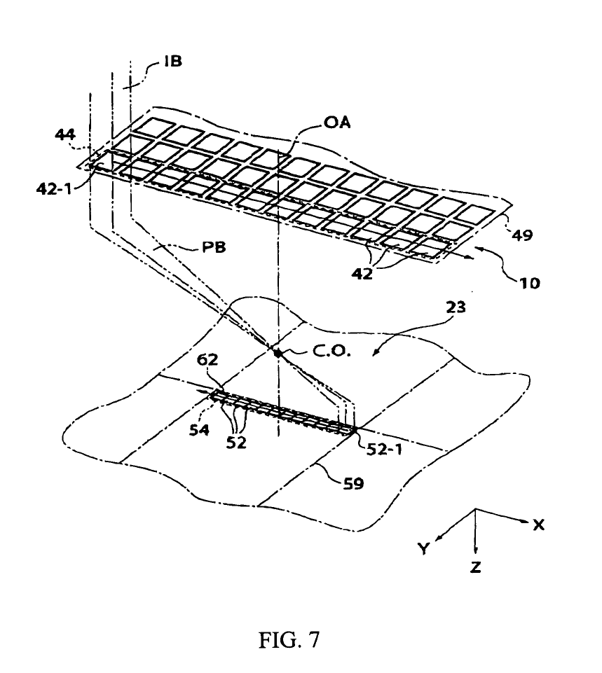

An overview of a charged-particle-beam (CPB) microlithography system, as exemplified by an electron-beam microlithography system, is set forth with reference to FIGS. 6 and 7. The system depicted in FIG. 6 uses a divided reticle (i.e., a reticle divided into subfields each defining a respective portion of the overall pattern) and can be used for mass-production of exposed wafers. FIG. 6 also depicts imaging and control relationships of the system.

Situated at the extreme upstream end of the system is an electron gun 1 that emits an electron beam propagating in a downstream direction generally along an optical axis Ax. Downstream of the electron gun 1 are a first condenser lens 2 and a second condenser lens 3, which collectively constitute a two-stage condenser-lens assembly. The condenser lenses 2, 3 converge the electron beam at a crossover C.O. situated on the optical axis Ax at a blanking diaphragm 7.

Downstream of the second condenser lens 3 and situated at the crossover C.O. is a “beam-shaping diaphragm” 4 comprising a plate defining an axial aperture (typically square or rectangular in profile) that trims and shapes the electron beam passing through the aperture. Thus, the beam is appropriately sized for illumination of only one subfield on the reticle 10 at a time. An image of the beam-shaping diaphragm 4 is formed on the reticle 10 by an illumination lens 9.

The electron-optical components situated between the electron gun 1 and the reticle 10 collectively constitute an “illumination-optical system” of the depicted microlithography system. The electron beam propagating through the illumination-optical system is termed an “illumination beam” because it illuminates a desired region of the reticle 10. As the illumination beam propagates through the illumination-optical system, the beam actually travels in a downstream direction through an axially aligned “beam tube” (not shown but well understood in the art) that can be evacuated to a desired vacuum level.

A blanking deflector 5 is situated downstream of the beam-shaping aperture 4. The blanking deflector 5 laterally deflects the illumination beam as required to cause the illumination beam to strike the aperture plate of the blanking diaphragm 7, thereby preventing the illumination beam from being incident on the reticle 10 during times in which exposure is not being performed.

A subfield-selection deflector 8 is situated downstream of the blanking diaphragm 7. The subfield-selection deflector 8 laterally deflects the illumination beam as required to illuminate a desired subfield situated on the reticle 10 within the optical field of the illumination-optical system. Thus, subfields of the reticle 10 are scanned sequentially by the illumination beam in a horizontal direction (X-direction in the figure). The illumination lens 9 is situated downstream of the subfield-selection deflector 8.

The reticle 10 typically defines a large number (e.g., thousands) of subfields (see, e.g., FIG. 7) arrayed in the X-Y plane. Typically, the subfields of a reticle collectively define the pattern for a layer to be formed at a single die (“chip”) on a lithographic substrate. Alternatively, defining the pattern for a single die can involve multiple reticles. A position-detection mark (not shown) is defined on a region of the reticle surface.

The reticle 10 is mounted on a movable reticle stage 11. The reticle stage 11 moves the reticle 10 in a direction (X- and Y-directions and combinations thereof) that is perpendicular to the optical axis Ax, thereby allowing respective subfields on the reticle 10, extending over a range that is wider than the optical field of the illumination-optical system, to be illuminated. The position of the reticle stage 11 in the X-Y plane is determined using a “position detector” 12 that typically is configured as a laser interferometer. The laser interferometer is capable of measuring the position of the reticle stage 11 with extremely high accuracy in real time.

Situated downstream of the reticle 10 are first and second projection lenses 15, 19, respectively, and an imaging-position deflector 16. The illumination beam, by passing through an illuminated subfield of the reticle 10, becomes a “patterned beam” because the beam downstream of the reticle carries an aerial image of the illuminated subfield. The patterned beam is imaged at a specified location on a substrate 23 (e.g., “wafer”) by the projection lenses 15, 19. To ensure imaging at the proper location on the substrate surface, the imaging-position deflector 16 imparts the required lateral deflection of the patterned beam.

So as to be imprintable with the image carried by the patterned beam, the upstream-facing surface of the substrate 23 is coated with a suitable “resist” that is imprintably sensitive to exposure by the patterned beam. When forming the image on the substrate 23, the projection lenses 15, 19 collectively “reduce” (demagnify) the aerial image. Thus, the image as formed on the substrate 23 is smaller (usually by a defined integer-ratio factor termed the “demagnification factor”) than the corresponding region illuminated on the reticle 10. By thus causing imprinting of the surface of the substrate 23, the system of FIG. 6 achieves “transfer” of the pattern image from the reticle 10 to the substrate 23. Further details regarding operation of the projection lenses 15, 19 and the imaging-position deflector 16 are discussed below with reference to FIG. 7.

The components of the depicted electron-optical system situated between the reticle 10 and the substrate 23 collectively are termed the “projection-optical system.” The substrate 23 is mounted to a substrate stage 24 situated downstream of the projection-optical system. As the patterned beam propagates through the projection-optical system, the beam actually travels in a downstream direction through an axially aligned “beam tube” (not shown but well understood in the art) that can be evacuated to a desired vacuum level.

The projection-optical system forms a crossover C.O. of the patterned beam on the optical axis Ax at the back focal plane of the first projection lens 15. The position of the crossover C.O. on the optical axis Ax is a point at which the axial distance between the reticle 10 and substrate 23 is divided according to the demagnification ratio. Situated between the crossover C.O. (i.e., the rear focal plane) and the reticle 10 is a contrast-aperture diaphragm 18. The contrast-aperture diaphragm 18 comprises an aperture plate that defines an aperture centered on the axis Ax. With the contrast-aperture diaphragm 18, electrons of the patterned beam that were scattered during transmission through the reticle 10 are blocked so as not to reach the substrate 23.

An alignment mark (not shown) is defined on the substrate 23 for use in detecting the position of the substrate. The alignment mark typically is an aggregate of multiple band-shaped pattern elements formed by, e.g., etching respective grooves into the surface of the substrate or forming respective band-shaped regions, on the surface of the substrate, of a heavy metal, such as Ta or W, exhibiting high reflectivity to incident electrons.

A backscattered-electron (BSE) detector 22 is situated immediately upstream of the substrate 23. The BSE detector 22 is configured to detect and quantify electrons backscattered from alignment mark(s) on the upstream-facing surface of the substrate 23 or on an upstream-facing surface of the substrate stage 24. For example, the alignment mark on the substrate 23 can be scanned by a beam that has passed through a corresponding mark pattern on the reticle 10. By detecting backscattered electrons from the alignment mark, it is possible to determine the relative positional relationship of the reticle 10 and the substrate 23.

The substrate 23 is mounted to the substrate stage 24 via a wafer chuck (not shown but well understood in the art), which presents the upstream-facing surface of the substrate 23 in an XY plane. The substrate stage 24 (with chuck and substrate 23) is movable in the X- and Y-directions. Thus, by simultaneously scanning the reticle stage 11 and the substrate stage 24 in mutually opposite directions, it is possible to transfer each subfield within the optical field of the illumination-optical system as well as each subfield outside the optical field to corresponding regions on the substrate 23. The substrate stage 24 also includes a “position detector” 25 configured similarly to the position detector 12 of the reticle stage 11.

A beam-current sensor 32 is provided on the substrate stage 24 for detecting the beam current (of the patterned beam) reaching the substrate stage 24. The beam-current sensor 32 can be, for example, a Faraday cup.

Each of the lenses 2, 3, 9, 15, 19 and deflectors 5, 8, 16 is controlled by a controller 31 via a respective coil-power controller 2a, 3a, 9a, 15a, 19a and 5a, 8a, 16a. Similarly, the controller 31, via respective stage drivers 11a and 24a, controls operation of the reticle stage 11 and substrate stage 24. The position detectors 12, 25 produce and route respective stage-position signals to the controller 31 via respective interfaces 12a, 25a each including amplifiers, analog-to-digital (A/D) converters, and other circuitry for achieving such ends. In addition, the beam-current sensor 32 and BSE detector 22 produce and route respective signals to the controller 31 via respective interfaces 32a, 22a, each including amplifiers, analog-to-digital (A/D) converters, and other circuitry for achieving such ends.

From the respective data routed to it, the controller 31 ascertains, inter alia, errors of the respective stage positions as a subfield is being transferred. To correct such errors, the imaging-position deflector 16 is energized appropriately to deflect the patterned beam. Thus, a reduced image of the illuminated subfield on the reticle 10 is transferred accurately to the desired target position on the substrate 23. This real-time correction is made as each respective image of a subfield is transferred to the substrate 23, and the images are positioned such that they are stitched together in a proper manner on the substrate 23.

Certain operational details of the projection-optical system of the microlithography system of FIG. 6 are shown in FIG. 7, which is a perspective view schematically showing the manner of transfer of an image of a single subfield on the reticle 10 to the surface of the substrate 23. On the reticle 10, the subfields are arrayed rectilinearly in rows and columns. A rectilinear array of multiple parallel rows each containing multiple respective subfields is termed a “stripe.” The width of each stripe corresponds to the length of each row, which corresponds to the width of the optical field of the illumination-optical system and projection-optical system. Since the width of the optical field corresponds to the maximum sweep width of the beam that is achievable by the electrically energized subfield-selection deflector 8, each row also is termed an “electrical stripe.” The stripe comprising multiple rows (electrical stripes) also is termed a “mechanical stripe” because exposure of the stripe requires coordinated mechanical movements of the reticle stage 11 and substrate stage 24.

In FIG. 7 a portion of a mechanical stripe 49 is shown (namely, three electrical stripes (rows) 44 of the mechanical stripe 49 are shown). Each electrical stripe 44 contains multiple subfields 42. Situated downstream of and parallel to the reticle 10 is the substrate 23 (e.g., a resist-coated semiconductor wafer). In FIG. 7 the subfield 42-1 in the left corner of the nearest electrical stripe 44 on the reticle 10 is illuminated from upstream by the illumination beam IB. Upon passing through the illuminated subfield 42-1, the illumination beam IB carries an aerial image of the respective pattern portion defined in the subfield 42-1 and thus becomes a patterned beam PB. The patterned beam PB is projected, with demagnification, by the projection-optical system (namely, the projection lenses 15, 19 and imaging-position deflector 16) onto a prescribed corresponding region 52-1 on the substrate 23 (FIG. 6).

Between the reticle 10 and the substrate 23, the patterned beam PB is deflected twice by the action of the two projection lenses 15, 19. The first deflection is from a direction parallel to the optical axis OA to a direction that intersects the optical axis, and the second deflection is from a direction intersecting the optical axis to a direction parallel to the optical axis. The exact location 52-1 at which the subfield image is formed is controlled with high accuracy and precision to ensure that all the subfield images are properly “stitched” together on the substrate, by which is meant that the images are contiguous with each other and properly aligned so as to form an unbroken image of the entire pattern collectively defined by all the subfields. Proper location of the images is achieved by appropriate energization of the imaging-position deflector 16.

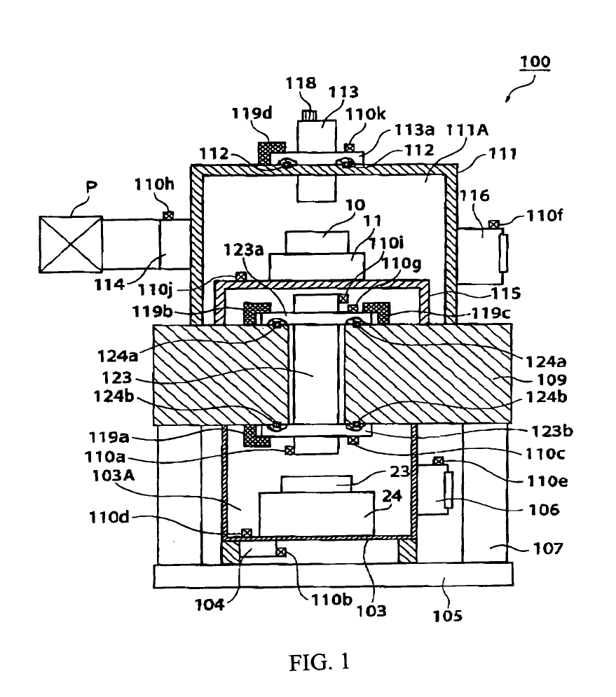

A representative embodiment of a microlithography system 100 according to an aspect of the invention is shown in FIGS. 1-5, in which components similar to corresponding components shown in FIG. 6 have the same respective reference numerals. The embodiment of FIGS. 1-5 is configured as an electron-beam microlithography system, as an exemplary CPB microlithography system. Referring first to FIG. 1, which is an elevational (and partial sectional) view, the system 100 comprises a support structure 109 mounted by a vibration-attenuating stand 107 to a base 105. A reticle chamber 111 is mounted to the “upper” surface of the support structure 109, and a wafer chamber 103 is mounted to the “lower” surface of the support structure 109. The interior of the reticle chamber 111 is a respective vacuum chamber 111A, and the interior of the wafer chamber 103 is a respective vacuum chamber 103A.

The reticle stage 11 is mounted, in the vacuum chamber 111A, to a reticle-stage base 115 mounted on an upstream-facing surface of the support structure 109. Thus, the reticle stage 11 is movable relative to the reticle-stage base 115. A reticle 10 is mounted on the reticle stage 11 for exposure and/or alignment purposes. Similarly, the substrate stage 24 is mounted, in the vacuum chamber 103A, to a substrate-stage base (not shown) mounted on the bottom wall of the wafer chamber 103. A substrate (wafer) 23 is mounted on the substrate stage 24 for exposure and/or alignment purposes.

An illumination-optical-system (IOS) column 113 is situated at an upstream end of the reticle chamber 111. The IOS column 113 extends through an “upper” wall of the reticle chamber 111. The electron gun 1, condenser lenses 2, 3, and deflectors 5, 8 (FIG. 6) are all situated inside the IOS column 113. External to the IOS column 113 at about mid-length is a mounting flange 113a. A seal 112 is interposed between the mounting flange 113a and the “upper” wall of the reticle chamber 111. Attached to the IOS column 113 is a damper 118, such as a dynamic vibration attenuator or a mass-damper system, which serves to restrict vibrations and other displacements of the IOS column 113.

A vacuum system 114 is mounted to the side (left side in the figure) of the reticle chamber 111. The vacuum system 114, in communication with so as to evacuate the vacuum chamber 111A, includes a turbomolecular pump P. A load chamber 116 (including feed-through gate valves and a manipulator) is mounted to the side (right side in the figure) of the reticle chamber 111. The load chamber 116 is used for conveying reticles 10 into and out of the vacuum chamber 111A.

Extending perpendicularly through the center of the support structure 109 between the reticle-stage base 115 and the substrate stage 23 is a projection-optical-system (POS) column 123. The POS column includes an “upper” flange 123a and a “lower” flange 123b on the upstream and downstream ends, respectively. A seal 124a is interposed between the upper flange 123a and the “upper” surface of the support structure 109, and a seal 124b is situated between the lower flange 123b and the “lower” surface of the support structure 109. The projection lenses 15, 19 and imaging-position deflector 16, as well as other electron-optical components as required, are arranged within the POS column 123.

A vacuum system 104 is mounted to the “lower” wall of the wafer chamber 103. The vacuum system 104, in communication with so as to evacuate the vacuum chamber 103A, includes a turbomolecular pump. A load chamber 106 (including feed-through gate valves and a manipulator) is mounted to the side (right side in the figure) of the wafer chamber 103. The load chamber 106 is used for conveying substrates 23 into and out of the vacuum chamber 103A.

The depicted system 100 also includes multiple displacement sensors 110a-110k, discussed below. The displacement sensors 110a-110k can be selected, as appropriate, from various acceleration sensors, force sensors, relative-movement sensors, and the like.

The displacement sensor 110a is attached to or near the downstream end of the POS column 123 within the wafer chamber 103. The displacement sensor 110a is used for detecting vibrations and other mechanical displacements of the downstream end of the POS column 123.

The displacement sensor 110b is attached to the vacuum system 104 connected to the wafer chamber 103. The displacement sensor 110b is used for detecting vibrations and other mechanical displacements of the turbomolecular pump of the vacuum system 104.

The displacement sensor 110c is attached to the “lower” (downstream-facing) surface of the flange 123b of the POS column 123 within the wafer chamber 103. The displacement sensor 110c is used for detecting vibrations and other displacements of the flange 123b as mounted to the support structure 109.

The displacement sensor 110d is attached in the vicinity of the substrate-stage base (not shown) mounted to the bottom wall of the wafer chamber 103. The displacement sensor 110d is used for detecting vibrations and other displacements of the bottom wall, caused principally by movements of the substrate stage 24.

The displacement sensor 110e is attached to the load chamber 106 extending from the side of the wafer chamber 103. The displacement sensor 110e is used for detecting vibrations and other displacements caused by operation of the gate valves and manipulator in the load chamber 106.

The displacement sensor 110f is attached to the load chamber 116 extending from the side of the reticle chamber 111. The displacement sensor 110f is used for detecting vibrations and other displacements caused by operation of the gate valves and manipulator in the load chamber 116.

The displacement sensor 110g is attached to the “upper” (upstream-facing) surface of the flange 123a of the POS column 123 downstream of the reticle-stage base 115 within the reticle chamber 111. The displacement sensor 110g is used for detecting vibrations and other displacements of the flange 123a as mounted to the support structure 109.

The displacement sensor 110h is attached to the vacuum system 114 connected to the reticle chamber 111. The displacement sensor 110h is used for detecting vibrations and other mechanical displacements of the turbomolecular pump P of the vacuum system 114.

The displacement sensor 110i is attached to the upstream end of the POS column 123, just downstream of the reticle table 115 and within the reticle chamber 111. The displacement sensor 110i is used for detecting vibrations and other mechanical displacements of the upstream end of the POS column 123.

The displacement sensor 110j is attached in the vicinity of the reticle-stage base 115 within the reticle chamber 111. The displacement sensor 110j is used for detecting vibrations and other mechanical displacements of the reticle-stage base 115, caused principally by movements of the reticle stage 11.

The displacement sensor 110k is attached to the “upper” surface of the flange 113a of the IOS column 113, outside the reticle chamber 111. The displacement sensor 110k detects vibrations and other mechanical displacements of the IOS column 113.

The microlithography system 100 also includes displacement actuators 119a-119d. By way of example, the displacement actuators 119a-119d can be respective piezoelectric elements or respective electromagnetic actuators (e.g., voice-coil motors). In the depicted embodiment the displacement actuator 119a is attached to the lower flange 123b of the POS column 123. The displacement actuators 119b and 119c are attached to the upper flange 123a of the POS column 123. The displacement actuator 119d is attached to the mounting flange 113a of the IOS column 113.

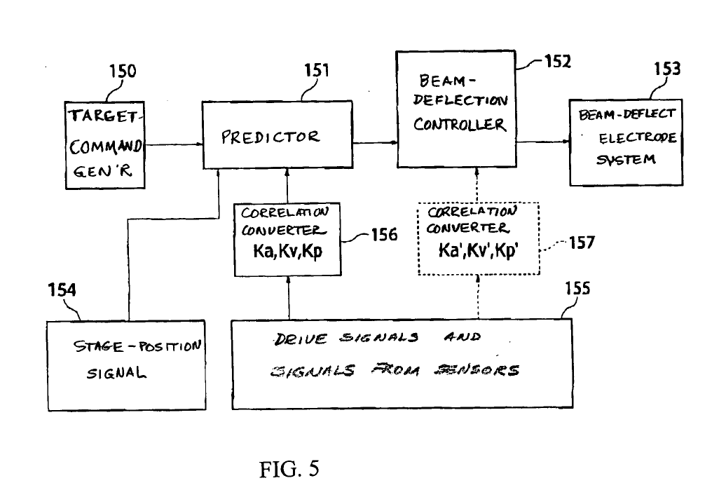

The displacement actuators 119a-119d in this embodiment are responsive to data obtained by the displacement sensors 110a-110k. Displacements detected by the displacement sensors 110a-110k are converted by the displacement sensors into corresponding electrical signals that are fed-back or fed-forward to the displacement actuators 119a-119d directly to a beam-control system (see dashed-line arrows in FIG. 5, discussed later below) or indirectly to a predictor 151 (FIG. 5), as discussed later below.

The number and respective locations of the displacement sensors 110a-110k and displacement actuators 119a-119d actually shown in FIG. 1 are not intended to be limiting. More or fewer displacement sensors and displacement actuators can be used in the system 100 as required.

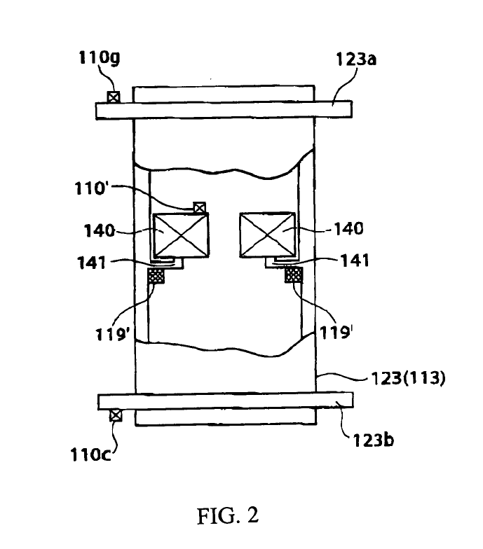

An embodiment of a column (i.e., the IOS column or POS column) of a microlithography system is shown in FIG. 2 as an elevational (and partial section) view. Specifically, FIG. 2 shows a POS column 123 including a “beam-position-control” portion 140 (e.g., the imaging-position deflector 16). The beam-position-control portion 140 is supported on a support member 141 within the POS column 123. A displacement sensor 110′, mounted on the beam-position-control portion 140, detects vibrations and other displacements of the beam-position-control portion 140 caused by external forces. A displacement actuator 119′ (e.g., a piezoelectric actuator) is mounted in the vicinity of the support member 141 and used for isolation and cancellation of the detected displacement. Electrical signals, generated by the displacement sensor 110′ and corresponding to displacements detected by the sensor 110′, are fed-back or fed-forward to the displacement actuator 119′, which is actuated in response to the signals in a manner serving to isolate and cancel the displacements. Thus, displacement-isolation control is provided to the beam-position-control portion 140. In the embodiment of FIG. 2, any magnetic field produced by the electromagnetic actuator 119′ is shielded so as not to have an adverse influence on the electron beam.

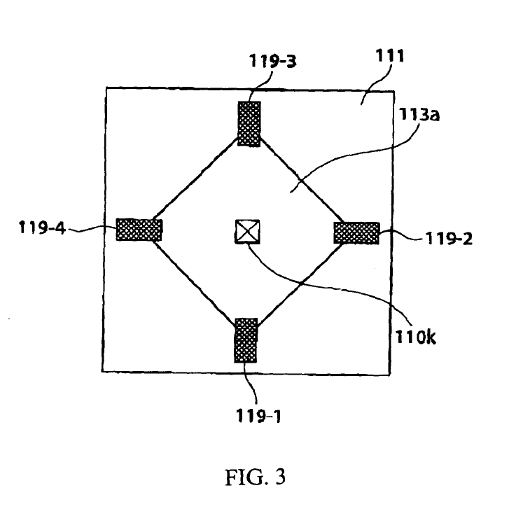

FIG. 3 is a plan view showing an exemplary arrangement of displacement actuators at one location in the IOS column 113 of a microlithography system. Specifically, in FIG. 3, the depicted arrangement is of the displacement actuator 119d in the vicinity of the mounting flange 113a, wherein the displacement actuator 119d comprises four individual displacement actuators 119-1 to 119-4 each situated at a respective corner of the mounting flange 113a. A displacement sensor 110k is situated at the center of the mounting flange 113a. An electrical signal produced by the displacement sensor 110k in response to displacements detected by the sensor 110k is fed-back or fed-forward to the respective displacement actuators 119-1 to 119-4, which are energized (in response to the signals) in a manner serving to cancel the displacements. Thus, displacement-isolation control is provided to the mounting flange 113a of the IOS column 113.

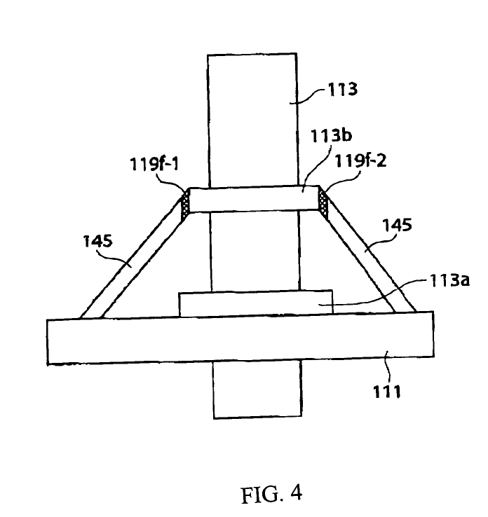

FIG. 4 is an elevational view showing an exemplary manner in which the IOS column 113 is mounted and supported with respect to the reticle chamber 111 of a microlithography system. The IOS column 113 in this example includes an intermediate mounting flange 113b situated upstream of the mounting flange 113a. The intermediate mounting flange 113b is mounted to the distal ends of braces 145 having proximal ends mounted to the upper wall of the reticle chamber 111. Respective displacement actuators 119f-1, 119f-2 are interposed between the mounting flange 113b and the distal ends of the braces 145.

A block diagram of a representative embodiment of a displacement-compensation system of the microlithography system 100 is shown in FIG. 5. The depicted system detects potentially troublesome vibrations and other displacements, and triggers offsetting shifts in beam position that cancel the effects of the displacements. The solid-line arrows in FIG. 5 denote controlled positional manipulations of the stage as performed at respective times. A target beam-position command, determined based on certain stage-position information at a certain time, is output by a target-command generator 150 to a predictor 151. The predictor 151 receives drive signals routed to various components of the microlithography system 100 that represent potential sources of displacement (e.g., the respective drive actuators of the reticle stage 11 and substrate stage 24, the respective turbomolecular pumps P of the vacuum systems 104, 114, and the respective gate valves and manipulators of the load chambers 106, 116). From these drive signals the predictor 151 calculates (using correlation factors Kₐ, Kᵥ, Kₚ pertaining to estimated acceleration, velocity, and position, respectively, of the substrate) estimates of the positional error of the electron beam that would be caused by actuation of these displacement sources, and corrects the calculated position error by feed-forward control of respective displacement actuators.

For example, the predictor 151 receives fed-forward stage-position signals 154 (e.g., stage position, stage velocity, stage acceleration), as determined by the stage-position detectors 12, 25, as well as stage-position or substrate-position signals 155 converted by a correlation converter 156. From these input signals the predictor 151 calculates corresponding beam-position errors and produces correction signals useful for correcting the errors. The correction signals are routed in a feed-forward manner to a beam-deflection controller 152 (e.g., the beam-position-control portion of the IOS column 113 or of the POS column 123), which routes appropriate drive signals to a beam-deflection electrode system 153. Thus, the position of the electron beam is feed-forward controlled by the beam-deflection controller 152 and the beam-deflection electrode system 153.

The signals received by the predictor 151 from the correlation converter 156 are converted signals. The conversions are based on the factors Kₐ, Kᵥ, and Kₚ, which represent respective correlations of displacement-sensor signals with actual stage or substrate position. The factors Kₐ, Kᵥ, Kₚ also take into account other variables that can adversely affect exposure accuracy, such as a change arising between the moment at which a sensor signal is generated and the moment at which a beam-deflection signal is produced for deflecting the beam to a desired location on the reticle or substrate. The factors Kₐ, Kᵥ, Kₚ also take into account positional tolerances of various components (e.g., deflectors and/or lenses) in the respective column.

As indicated by the dashed line in FIG. 5, a separate correlation converter 157 can be used instead of the correlation converter 156 for inputting beam-acceleration, beam-velocity, and beam-position factors Kₐ′, Kᵥ′, Kₚ′ to beam-position signals 155 routed directly to the beam-deflection controller 152. Thus, the position of the electron beam used for making exposures is established by feed-forward control of the beam-deflection electrode system 153 by the beam-deflection controller 152.

These control schemes also can be applied to situations in which the overall structure of the microlithography system is different from that shown in FIG. 1. For example, the microlithography system can be configured such that both load chambers are separately installed and/or such that the reticle chamber, the wafer chamber, the POS column, and IOS column are separately supported.

From the foregoing description, it will be appreciated that beam-position errors attributable to displacements of the lens column (or of components thereof) and/or of other assemblies of the microlithography system can be reduced significantly. Reduction of these errors can be achieved during actual exposures being performed by the system, during times in which a reticle or substrate is being conveyed to or from the system, or during times in which the reticle stage and/or substrate stage are moving. Thus, the corrective actions described herein have no adverse effect on throughput.

Whereas the invention has been described in connection with multiple representative embodiments, it is not limited to those embodiments. On the contrary, the invention is intended to encompass all modifications, alternatives, and equivalents as may be included within the spirit and scope of the invention, as defined by the appended claims.

What is claimed is:

1. A charged-particle-beam (CPB) microlithography system that selectively irradiates a charged particle beam onto a sensitive substrate to imprint a pattern on the substrate, the system comprising:
a CPB-optical column situated upstream of the substrate and comprising a beam-position-control portion that deflects and resolves a charged particle beam for making a lithographic exposure of the pattern on the sensitive substrate;
at least one displacement sensor attached to a location in or on the CPB-optical column and configured to detect displacements, that could produce a beam-position error, of the location and to produce electrical signals corresponding to the detected displacements; and
a beam-corrector connected so as to receive the electrical signals from the at least one displacement sensor and to produce beam-correction signals corresponding to the electrical signals, the beam-correction signals being received by the beam-position-control portion which imparts a corresponding correction to the beam serving to correct the beam-position error.

2. The system of claim 1, wherein the beam-position-control portion comprises at least one CPB lens and at least one CPB deflector.

3. The system of claim 1, wherein the correction is associated with at least one of changes in deflection of the beam and changes in lensing of the beam.

4. The system of claim 1, wherein the displacement sensor is selected from the group consisting of acceleration sensors, force sensors, and relative-movement sensors.

5. The system of claim 1, wherein the CPB-optical column comprises an illumination-optical-system column.

6. The system of claim 5, wherein the beam-corrector is situated and configured to impart a correction to the beam propagating through the illumination-optical-system column.

7. The system of claim 1, wherein the CPB-optical column comprises a projection-optical-system column.

8. The system of claim 7, wherein the beam-corrector is situated and configured to impart a correction to the beam propagating through the projection-optical-system column.

9. The system of claim 7, wherein the CPB-optical column further comprises an illumination-optical-system column.

10. The system of claim 9, wherein the beam-corrector is situated and configured to impart a correction to the beam propagating through the illumination-optical system or projection-optical system as required to correct the beam-position error.

11. The system of claim 1, wherein:
the CPB-optical column comprises a reticle chamber and a wafer chamber each containing a subatmospheric-pressure environment produced by a vacuum system connected to the CPB-optical column; and
the detected displacements including vibration of at least one of the chambers caused by operation of the vacuum system.

12. The system of claim 1, comprising multiple displacement sensors attached to respective locations on or in the CPB-optical column, for detecting respective displacements of the locations.

13. The system of claim 12, wherein the multiple displacement sensors are attached to respective components of the CPB-optical column, so as to detect respective displacements of the respective components.

14. The system of claim 13, wherein:
the components include respective components of the beam-position-control portion; and
the respective displacements arise from energization of the respective components.

15. The system of claim 1, wherein the beam-corrector comprises at least one actuator situated relative to a component of the beam-position-control portion and configured to impart a respective positional shift of the component in response to the beam-correction signal, the positional shift serving to correct the beam-position error.

16. The system of claim 1, wherein the beam-corrector comprises a processor connected to the at least one displacement sensor, the processor being configured to (i) ascertain, from the electrical signals from the at least one displacement sensor, whether a beam correction is indicated to correct an effect of the displacement, (ii) if beam correction is indicated, to produce the beam-correction signals corresponding to the electrical signals, and (iii) route the beam-correction signals to the beam-position-control portion to impart the correction to the beam serving to correct the beam-position error.

17. The system of claim 16, wherein the processor causes the beam-position-control portion to impart a compensating manipulation of the beam to correct the beam-position error.

18. The system of claim 17, wherein the compensating manipulation is a deflection of the beam.

19. The system of claim 17, wherein:
the processor controls, in a feed-back manner, operation of the beam-position-control portion to perform a compensating manipulation of the beam; and
the compensating manipulation is in real time with respect to the displacement.

20. The system of claim 1, wherein the beam-corrector comprises a predictor that computes an estimated beam-position error from the detected displacement of the location and produces the beam-correction signals in a feed-forward manner.

21. The system of claim 20, wherein the predictor:
receives drive signals routed to components of the microlithography system;
calculates estimates of beam-position error that could be caused by energization of the components according to the drive signals; and
corrects the calculated beam-position error by feed-forward control of the beam-corrector.

22. The system of claim 21, further comprising a stage situated and configured to hold a reticle or the substrate in the CPB-optical column.

23. The system of claim 22, wherein the beam-corrector imparts, in response to receiving the beam-correction signals, a compensating motion of the stage.

24. The system of claim 1, further comprising a stage situated and configured to hold a reticle or the substrate in the CPB-optical column.

25. The system of claim 24, wherein the beam-corrector imparts, in response to receiving the beam-correction signals, a compensating motion of the stage for correcting the beam-position error.

26. A charged-particle-beam (CPB) microlithography system that selectively irradiates a charged particle beam onto a sensitive substrate to imprint a pattern on the substrate, the system comprising:
a CPB-optical system that includes a beam-position-control portion that controllably deflects and resolves a charged particle beam for making a lithographic exposure of the pattern on the sensitive substrate;
a stage situated relative to the CPB-optical system and configured to hold and controllably move a pattern-defining reticle or the substrate during the making of the lithographic exposure;
an interferometer situated relative to the stage and configured to determine a position of the stage;
at least one displacement sensor attached to a respective location on at least one of the stage and interferometer, the displacement sensor being configured to detect a displacement of the location, including a displacement producing a beam-position error that could degrade accuracy of the lithographic exposure, and to produce electrical signals corresponding to the detected displacement; and
a beam-corrector connected so as to receive the electrical signals from the at least one displacement sensor and to produce beam-correction signals corresponding to the electrical signals, the beam-correction signals being received by the beam-position-control portion which imparts a correction to the beam serving to correct the beam-position error.

27. The system of claim 26, wherein:
the CPB-optical system comprises an illumination-optical-system column and a projection-optical-system column each including respective beam-position-control portions; and
the respective beam-position-control portions receive beam-correction signals so as to impart respective corrections to the beam.

28. The system of claim 27, comprising multiple stages, including a reticle stage situated relative to the illumination-optical-system column and configured to hold a pattern-defining reticle, and a substrate stage situated relative to the projection-optical-system column and configured to hold the sensitive substrate, each of the reticle stage and substrate stage including a respective interferometer.

29. The system of claim 28, comprising multiple displacement sensors including respective displacement sensors coupled to the illumination-optical-system column, the projection-optical-system column, the reticle stage, and the substrate stage.

30. The system of claim 28, wherein the beam-corrector is configured to produce respective beam-correction signals for the respective beam-position-control portions of the illumination-optical-system column and projection-optical-system column as required to correct a displacement detected in one or both columns.

31. The system of claim 26, wherein the beam-corrector comprises at least one actuator situated relative to a component of the beam-position-control portion and configured to impart a respective positional shift of the component in response to the beam-correction signal, the positional shift serving to correct the beam-position error.

32. The system of claim 26, wherein the beam-corrector comprises a processor connected to the at least one displacement sensor, the processor being configured to (i) ascertain, from the electrical signals from the at least one displacement sensor, whether a beam correction is indicated to correct an effect of the displacement, (ii) if beam correction is indicated, to produce the beam-correction signals corresponding to the electrical signals, and (iii) route the beam-correction signals to the beam-position-control portion to impart the correction to the beam serving to correct the beam-position error.

33. The system of claim 26, wherein the beam-corrector comprises a predictor that computes an estimated beam-position error from the detected displacements of the location and produces the respective beam-correction signals in a feed-forward manner.

34. The system of claim 26, wherein the predictor:
receives drive signals routed to components of the microlithography system;
calculates estimates of beam-position error that could be caused by energization of the components according to the drive signals; and
corrects the calculated beam-position error by feed-forward control of the beam-corrector.

35. A charged-particle-beam (CPB) microlithography system that selectively irradiates a charged particle beam onto a sensitive substrate to imprint a pattern on the substrate, the system comprising:
a CPB-optical system that includes a beam-position-control portion that controllably deflects and resolves the charged particle beam for making a lithographic exposure of the pattern on the sensitive substrate;
a stage situated relative to the CPB-optical system and configured to hold and controllably move a pattern-defining reticle or the substrate during the making of the lithographic exposure;
an interferometer situated relative to the stage and configured to determine a position of the stage;
multiple displacement sensors attached to respective locations on the stage or interferometer, and on the CPB-optical system or beam-position-control portion, the displacement sensors being configured to detect a displacement of the respective location, including displacements that could produce a beam-position error that degrades accuracy of the lithographic exposure, and to produce respective electrical signals corresponding to the detected displacements; and
a beam-corrector connected so as to receive the electrical signals from the displacement sensors and to produce respective beam-correction signals that are routed to and received by the beam-position-control portion, which imparts a respective correction to the beam serving to correct the beam-position error.

36. The system of claim 35, wherein the beam-corrector comprises a predictor that computes an estimated beam-position error from the detected displacements of the respective locations and produces the respective beam-correction signals in a feed-forward manner.

37. The system of claim 35, wherein the predictor:
receives drive signals routed to components of the microlithography system;
calculates estimates of beam-position error that could be caused by energization of the components according to the drive signals; and
corrects the calculated beam-position error by feed-forward control of the beam-corrector.

38. The system of claim 37, further comprising a correlation converter connected to the predictor, the correlation converter producing electrical signals based on a correlation of at least one drive signal with substrate location, and routing these electrical signals to the predictor which calculates the estimates of beam-position error based at least in part on these electrical signals.

39. The system of claim 38, further comprising a beam-deflection controller connected to the predictor, the beam-deflection controller causing deflection of the beam, according to the beam-correction signals, as required to correct the beam-position error.

40. A charged-particle-beam (CPB) microlithography system that selectively irradiates a charged particle beam onto a sensitive substrate to imprint a pattern on the substrate, the system comprising:
a CPB-optical system, situated upstream of the substrate, comprising an optical column and a beam-position-control portion, the beam-position-control portion controllably deflecting and resolving a charged particle beam for making a lithographic exposure of the pattern on the sensitive substrate, the optical column comprising a vacuum chamber to which is connected a vacuum system;
a stage situated relative to the CPB-optical system and configured to hold a pattern-defining reticle or the substrate during the making of the lithographic exposure, the stage including a stage actuator configured to move the stage in a controlled manner;
multiple displacement sensors attached to respective locations, including the stage actuator and vacuum system, that tend to produce displacements, the displacement sensors being configured to detect the displacements at the respective locations, and to produce respective electrical signals corresponding to the detected respective displacements; and
a beam-corrector connected so as to receive the electrical signals from the displacement sensors, the beam-corrector comprising a predictor configured to calculate estimates of displacement of one or more of the optical column, the beam-position-control portion, the vacuum system, and the stage, and being configured to correct, based on the estimates provided by the predictor, the beam-position error by feed-forward control.

41. The system of claim 40, further comprising a correlation converter connected to the predictor, the correlation converter producing electrical signals based on data concerning a correlation of at least one displacement-sensor signal with substrate location, and routing these electrical signals to the predictor which calculates the estimates of beam-position error based at least in part on these electrical signals.

42. The system of claim 41, further comprising a beam-deflection controller connected to the predictor, the beam-deflection controller causing deflection of the beam, according to the beam-correction signals, as required to correct the beam-position error.

43. A charged-particle-beam (CPB) microlithography system that selectively irradiates a charged particle beam onto a sensitive substrate to imprint a pattern on the substrate, the system comprising:
a CPB-optical system, comprising a beam-position-control portion and a vacuum chamber to which is connected a vacuum system, the beam-position-control portion controllably deflecting and resolving a charged particle beam for making a lithographic exposure of the pattern on the sensitive substrate;
a stage situated relative to the CPB-optical system and configured to hold a pattern-defining reticle or the substrate during the making of the lithographic exposure, the stage including a stage actuator configured to move the stage in a controlled manner;
a processor connected to the beam-position-control portion, the vacuum system, and the stage actuator and configured to produce, in a coordinated manner, respective drive signals for the beam-position-control portion, the vacuum system, and the stage actuator; and
a beam-corrector comprising a predictor configured to (i) receive the drive signals, (ii) calculate estimates of respective displacements caused by driving the beam-position-control portion, the vacuum system, and the stage, and (iii) calculate an expected beam-position error caused by the displacements, the beam-corrector being configured to correct the beam-position error by feed-forward control.

44. The system of claim 43, further comprising a correlation converter connected to the predictor, the correlation converter producing electrical signals based on data concerning correlations of at least one drive signal with substrate location, and routing these electrical signals to the predictor which calculates the estimates of beam-position error based at least in part on these electrical signals.

45. The system of claim 44, further comprising a beam-deflection controller connected to the predictor, the beam-deflection controller causing deflection of the beam, according to the beam-correction signals, as required to correct the beam-position error.

46. A charged-particle-beam (CPB) microlithography system that selectively irradiates a charged particle beam onto a sensitive substrate to imprint a pattern on the substrate, the system comprising:
a CPB-optical system, situated upstream of the substrate, comprising an optical column and a beam-position-control portion, the beam-position-control portion being configured to deflect and resolve, in a controlled manner, a charged particle beam for making a lithographic exposure of the sensitive substrate;
multiple displacement sensors attached to respective locations on the optical column and the beam-position-control portion, and configured to detect displacements of the respective locations that could adversely impart a beam-position error and to produce electrical signals corresponding to the detected displacements; and
at least one damping actuator attached to the lens column or beam-position-control portion and configured to receive the electrical signals from the displacement sensors and to restrict, based on the signals, displacement of the optical column or beam-position-control portion.

47. The system of claim 46, further comprising a processor that receives the electrical signals corresponding to the detected displacements, and processes the electrical signals to produce drive signals for at least one of the optical column and beam-position-control portion; the drive signals causing the displacement of the optical column or beam-position-control portion.

48. The system of claim 46, wherein the damping actuator is an electromagnetic actuator or a piezoelectric actuator.

49. A charged-particle-beam (CPB) microlithography system that selectively irradiates a charged particle beam onto a sensitive substrate to imprint a pattern on the substrate, the system comprising:
a component that, when actuated, produces a displacement that, if unchecked, could produce an excessive beam-position error;
a displacement sensor attached to the component and configured to detect displacements of the component and to produce electrical signals corresponding to the detected displacements; and
a damping actuator attached to the component and connected to the displacement sensor so as to receive the electrical signals from the displacement sensor and being configured, when actuated, to attenuate the displacement of the component in a feed-forward manner.

50. The system of claim 49, wherein the component is of an assembly selected from the group consisting of a stage, a vacuum system, and a beam-position-control portion.

51. The system of claim 49, wherein the damping actuator responds to the displacement sensor in a feed-back controlled manner.

52. A charged-particle-beam (CPB) microlithography system that selectively irradiates a charged particle beam onto a sensitive substrate to imprint a pattern on the substrate, the system comprising:
a CPB-optical system, situated upstream of the substrate, comprising a beam-position-control portion that, when energized, controllably deflects and resolves the charged particle beam for making a lithographic exposure of the pattern on the sensitive substrate, the CPB-optical system being a part of an optical column to which a vacuum system is connected, the vacuum system being configured, when energized, to evacuate the optical column to a desired vacuum level;
a stage situated relative to the CPB-optical system and configured to hold, in the optical column, a pattern-defining reticle or the substrate during the making of the lithographic exposure, the stage including a stage actuator situated and configured, when energized, to move the stage in a controlled manner, wherein each of the optical column, the stage, and the beam-position-control portion being capable of producing, when energized, a respective beam-position error;
a controller connected to the beam-position-control portion, the vacuum system, and the stage actuator, the controller being configured to deliver respective drive signals to the beam-position-control portion, the vacuum system, and the stage actuator;
a predictor connected so as to receive the drive signals and configured to calculate estimates of respective displacements produced by the energized beam-position-control portion, the optical column, and the stage actuator; and
a respective damping actuator connected to at least one of the optical column, the beam-position-control portion, and the stage, the damping actuator being configured to restrict, in a feed-forward manner, the respective displacements based on the calculated estimates.

53. The system of claim 52, further comprising a correlation converter connected to the predictor, the correlation converter producing electrical signals based on data concerning correlations of at least one drive signal with substrate location, and routing these electrical signals to the predictor which calculates the estimates of beam-position error based at least in part on these electrical signals.

54. The system of claim 53, further comprising a beam-deflection controller connected to the predictor, the beam-deflection controller causing deflection of the beam, according to the beam-correction signals, as required to correct the beam-position error.

55. A charged-particle-beam (CPB) microlithography system that selectively irradiates a charged particle beam onto a sensitive substrate to imprint a pattern on the substrate, the system comprising:
a CPB-optical system, situated upstream of the substrate, comprising a CPB-optical column and a beam-position-control portion, the beam-position-control portion being configured to deflect and resolve the charged particle beam in a controlled manner for making a lithographic exposure of the pattern on the sensitive substrate; and
at least one displacement damper attached to the CPB-optical column or the beam-position-control portion and configured, when energized, to dampen displacements of the CPB-optical column or beam-position-control portion, respectively.

56. The system of claim 55, wherein the displacement damper is configured to dampen the displacement based on fed-forward data to the displacement damper concerning an expected displacement of the CPB-optical column or beam-position-control portion, respectively.

57. In a charged-particle-beam (CPB) microlithography method in which a pattern is selectively irradiated, by a charged particle beam passing through a CPB-optical column, onto a sensitive substrate so as to imprint the pattern on the substrate, a method for reducing a beam-position error accompanying a displacement of a location in or on the CPB-optical column, the method comprising:
detecting a displacement of the location; and
based on and in response to the displacement, imparting a corrective shift in a component of the CPB-optical system, the corrective shift serving at least to reduce the beam-position error.

58. The method of claim 57, wherein the corrective shift is in a component including the location.

59. The method of claim 57, wherein the corrective shift is in a component separate from the location.

60. The method of claim 57, wherein the corrective shift is made in real time relative to the displacement.

61. The method of claim 57, wherein the corrective shift is made in a feed-back controlled manner.

62. The method of claim 57, wherein the corrective shift is made in a feed-forward-controlled manner.

63. The method of claim 57, wherein the corrective shift includes a corrective deflection of the beam.

64. The method of claim 57, wherein the corrective shift includes a corrective lensing of the beam.

65. The method of claim 57, wherein the corrective shift includes a corrective change in position of a stage in the CPB-optical column.

66. The method of claim 57, wherein:
the corrective shift is in a component of the CPB-optical system; and
the corrective shift comprises energizing an actuator associated with the component.

67. The method of claim 57, wherein:
the corrective shift is in a component of the CPB-optical system; and
the corrective shift comprises making a change in energization of the component.

68. The method of claim 57, further comprising:
determining a predicted displacement of the location; and
imparting the corrective shift in response to the predicted displacement.

69. The method of claim 68, wherein the corrective shift is made in a feed-forward-controlled manner.

70. The method of claim 68, wherein the step of determining the predicted displacement comprises calculating, from data concerning drive signals supplied to at least one component of the CPB-optical system, a corresponding beam-position error accompanying actuation of the component according to the drive signals.

71. The method of claim 70, wherein the step of calculating the corresponding beam-position error includes taking into consideration data concerning correlations of beam-position data, beam-velocity data, and beam-acceleration data with actual beam position.
